(19) United States
(12) Patent Application Publication
(10) Pub. No.: US 2011/0149627 A1
(43) Pub. Date: Jun. 23, 2011

(54) NONVOLATILE MEMORY DEVICE AND METHOD OF OPERATING THE SAME

(76) Inventor: Won Kyung Kang, Seoul (KR)

(21) Appl. No.: 12/774,678

(22) Filed: May 5, 2010

(30) Foreign Application Priority Data
Dec. 21, 2009 (KR) 10-2009-0127960

(51) Int. Cl. G11C 15/00; G11C 7/22; G11C 5/14

(52) U.S. Cl. 365/49.1; 365/189.011; 365/226

(57) ABSTRACT

A nonvolatile memory device comprises a voltage detector for generating a detection signal when the external power supply voltage is higher than a set voltage and memory chips, each comprising a memory cell unit and a content-addressable memory (CAM) cell unit and performing internal operations in response to the detection signal.

### CROSS-REFERENCE TO RELATED APPLICATION

Priority to Korean patent application number 10-2009-0127960 filed on Dec. 21, 2009, the entire disclosure of which is incorporated by reference herein, is claimed.

### BACKGROUND

Exemplary embodiments relate to a nonvolatile memory device and a method of operating the same and, more particularly, to a nonvolatile memory device and a method of operating the same, which are capable of performing a stable operation by reading data from a content-addressable memory (hereinafter referred to as a ‘CAM’) cell after a power source stably rises up to a certain level during a power-on operation.

With the recent increasing demand for mobile products, such as camcorders, digital cameras, portable phones, and MPEG-1 Layer3 (MP3) players, further improvements in performance of nonvolatile memory devices for the operation of the mobile products are desired.

Designs of a nonvolatile memory device for a mobile product are determined based on the operating characteristics of a corresponding product, and the nonvolatile memory device operates in response to an application program.

With the development of new technologies, the number of application programs for a mobile product increases. Accordingly, an efficient way for handling various options for a nonvolatile memory device is desired.

A nonvolatile memory device may store option information in a fuse. However, because a fuse is relatively large and there is a need for high integration nonvolatile memory devices, a recent trend in nonvolatile memory devices is to store option information in a CAM cell.

The nonvolatile memory device storing the option information in the CAM cell requires an operation of loading data stored in the CAM cell during a reset operation and storing the loaded data in an internal register after a power-on operation. The operation of loading the data of the CAM cell is performed when a voltage level is stabilized to some extent after supplying a power source.

A typical nonvolatile memory device, when being supplied with external power source, generates a power-on signal in response to a level of the external power source and starts an operation of reading data stored in a CAM cell in response to the power-on signal. However, the power-on signal may have a varying voltage level during a power-on period since the power source is ramped up to a stable voltage with a slope. Here, if the rate with which the voltage of the power source rises is low, current consumption in reading the data stored in the CAM cell increases. Accordingly, a drop in the supplied power may occur, and the read operation may fail.

### BRIEF SUMMARY

Exemplary embodiments relate to a nonvolatile memory device and a method of operating the same, which are capable of stably reading data stored in a CAM cell by performing the read operation after an external power supply voltage rises to a certain voltage.

A nonvolatile memory device according to an aspect of this disclosure comprises a voltage detector for generating a detection signal when the external power supply voltage is higher than a set voltage and memory chips, each comprising a memory cell unit and a content-addressable memory (CAM) cell unit and performing internal operations in response to the detection signal.

Each of the memory chips comprises the CAM cell unit configured to store CAM cell data, a peripheral circuit unit coupled to the CAM cell unit and configured to read the CAM cell data in response to a read command, a control unit configured to generate the read command in response to the detection signal, and a register unit configured to temporarily store the read CAM cell data.

A nonvolatile memory device according to another aspect of this disclosure comprises a controller configured to generate an internal command in response to an external command and memory chips operated in response to the internal command. The controller outputs a command for controlling operations of the memory chips when an external power supply voltage is higher than a set voltage.

A nonvolatile memory device according to yet another aspect of this disclosure comprises memory chips, each comprising a memory cell unit and a CAM cell unit and performing internal operations in response to an internal command, a controller for generating the internal command in response to an external command, a voltage detector for comparing an external power supply voltage and a set voltage and outputting a detection signal based on a result of the comparison, and a transfer unit for transferring the internal command to the memory chips in response to the detection signal.

A method of operating a nonvolatile memory device according to still yet another aspect of this disclosure comprises gradually increasing an external power supply voltage, detecting the external power supply voltage, and generating a read command when the external power supply voltage is higher than a set voltage, reading CAM cell data in response to a read command and storing the read CAM cell data, and performing program, read, and erase operations using the stored CAM cell data.

A method of operating a nonvolatile memory device according to still yet another aspect of this disclosure comprises gradually increasing an external power supply voltage, inputting an external command to a controller to thereby generate an internal command, when the external power supply voltage is higher than a set voltage, transferring the internal command to memory chips, reading CAM cell data stored in the memory chips in response to the internal command, and performing program, read, and erase operations using the CAM cell data.

### BRIEF DESCRIPTION OF THE DRAWINGS

FIG. 1 is a diagram showing the constituents of a nonvolatile memory device according to an embodiment of this disclosure;

FIG. 2 is a voltage graph illustrating the operation of a voltage detector according to an embodiment of this disclosure;

FIG. 3 is a flowchart illustrating the operation of the nonvolatile memory device according to an embodiment of this disclosure; and

FIG. 4 is a diagram showing the construction of a nonvolatile memory device according to another embodiment of this disclosure.

### DESCRIPTION OF EMBODIMENTS

Hereinafter, exemplary embodiments of this disclosure will be described in detail with reference to the accompanying drawings. The figures are provided to facilitate understanding of the exemplary embodiments of the disclosure by those of ordinary skill in the art.

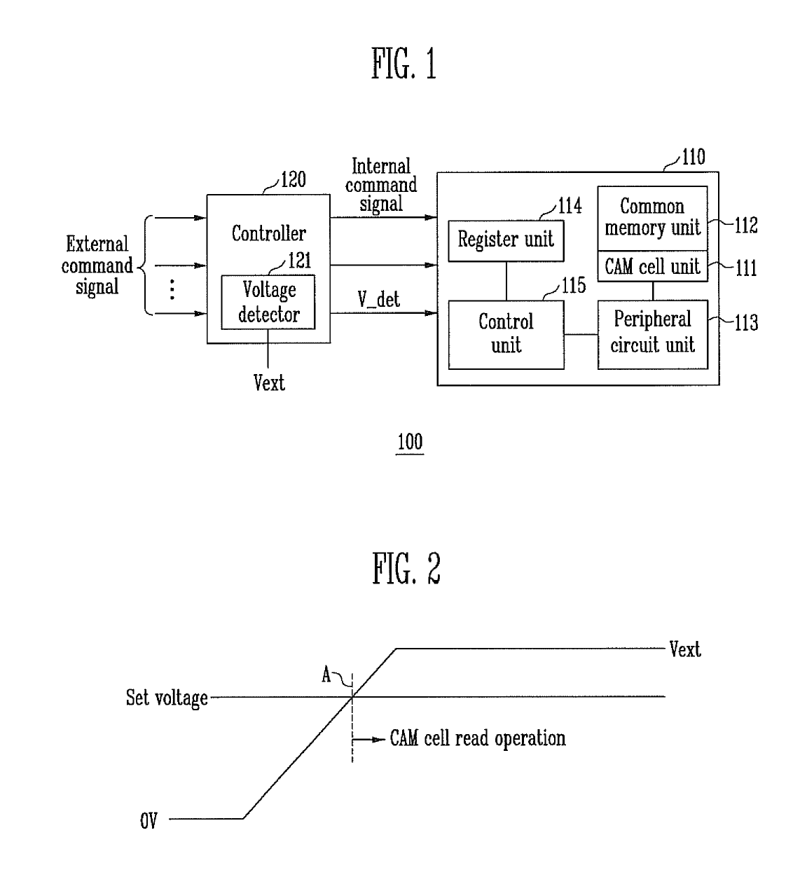

FIG. 1 is a diagram illustrating the constituents of a nonvolatile memory device according to an embodiment of this disclosure.

Referring to FIG. 1, the nonvolatile memory device 100 according to the embodiment of this disclosure includes one or more memory chips 110 and a controller 120.

Each of the memory chips 110 includes a CAM cell unit 111, a common memory unit 112, a peripheral circuit unit 113, a register unit 114, and a control unit 115. The CAM cell unit 111 stores option information for operating the memory chip 110. The peripheral circuit unit 113 includes a circuit for loading data stored in the CAM cell unit 111 and storing the loaded data at circuits such as a memory cell array and a page buffer which are typically included in the memory chip 110.

The register unit 114 temporarily stores option information stored in and retrieved from the CAM cell unit 111 during the operation of the memory chip 110. The control unit 115 performs a control operation in response to a command received from the controller 120 such that option information stored in and received from the CAM cell unit 111 is loaded and stored in the register unit 114.

The controller 120 includes a voltage detector 121.

The controller 120 enables one or more memory chips 110 and outputs operation commands to the memory chips 110. Further, the controller 120 generates the command such that option information stored in and received from the CAM cell unit 111 is loaded and stored in the register unit 114.

The voltage detector 121 detects an external power supply voltage Vext and, when the power supply voltage Vext is higher than a certain voltage, outputs a detection signal V_det. The control unit 115 of the memory chip 110 loads option information stored in and received from the CAM cell unit 111 in response to the detection signal V_det and stores the loaded option information in the register unit 114.

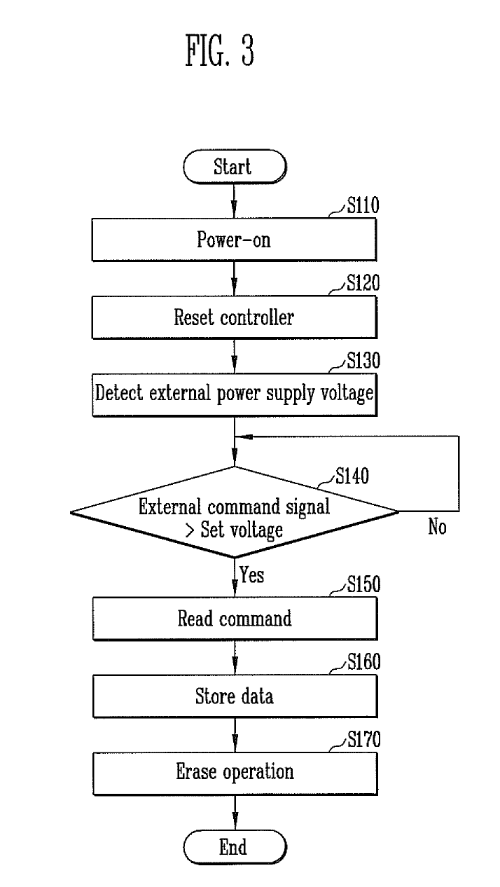

FIG. 2 is a voltage graph illustrating the operation of the voltage detector 121 according to an embodiment of this disclosure.

Referring to FIG. 2, when the external power supply voltage Vext rises during a power-on period, the voltage detector 121 outputs the detection signal V_det when the external power supply voltage Vext is higher than a set voltage (indicated by ‘A’). Here, the set voltage according to an example may be set to be equal to or greater than a voltage of the power source at which data stored in the CAM cell unit 111 can be read more stably.

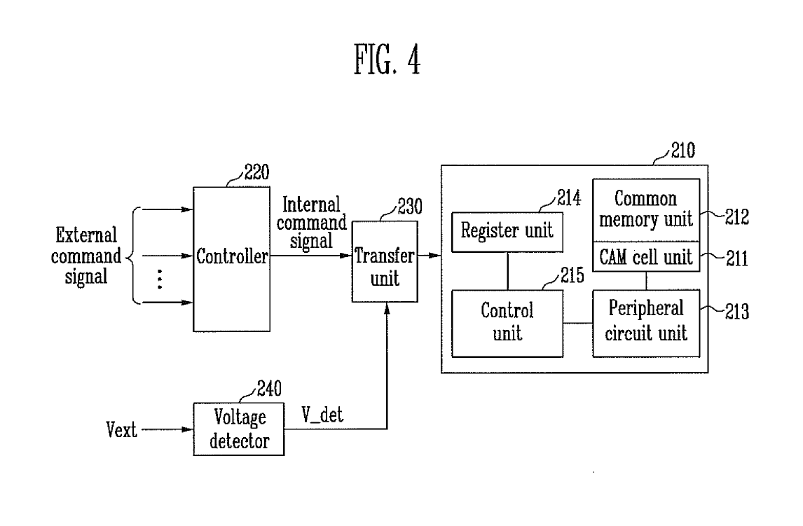

FIG. 3 is a flowchart illustrating the operation of the nonvolatile memory device according to an embodiment of this disclosure.

The operation of the nonvolatile memory device is described below with reference to FIGS. 1 to 3.

First, the external power supply voltage Vext which gradually rises is supplied to the nonvolatile memory device 100 and powers on the nonvolatile memory device 100 at step S110.

When the external power supply voltage Vext is supplied, the controller 120 is reset from a standby state at step S120.

The voltage detector 121 of the controller 120 detects the external power supply voltage Vext at step S130. The voltage detector 121 compares the detected external power supply voltage Vext and a set voltage and outputs the detection signal V_det based on a result of the comparison at step S140. If, as a result of the comparison, the external power supply voltage Vext is determined to be equal to or less than the set voltage, the voltage detector 121 does not output the detection signal V_det. If, as a result of the comparison, the external power supply voltage Vext is determined to be higher than the set voltage, the voltage detector 121 outputs the detection signal V_det.

Since the external power supply voltage Vext gradually rises, the voltage detector 121 eventually outputs the detection signal V_det when the external power supply voltage Vext becomes higher than the set voltage.

The control unit 115 of the memory chip 110 inputs a read command for reading data stored in and retrieved from a CAM cell of the CAM cell unit 111 to the peripheral circuit unit 113 in response to the detection signal V_det at step S150.

The peripheral circuit unit 113 reads the data stored in the CAM cell of the CAM cell unit 111 and stores the read data in the register unit 114 via the control unit 115 at step S160.

Next, the nonvolatile memory device performs operations (e.g., program, erase, and read operations) based on the data stored in the register unit 114 at step S170.

As described above, according to the embodiments of this disclosure, data stored in a CAM cell of the CAM cell unit 111 are read when the external power supply voltage Vext is higher than a set voltage, and then stored in the register unit 114. Accordingly, CAM cell data can be stably read, and so reliability of the operations of the nonvolatile memory device can be improved.

FIG. 4 is a diagram showing the construction of a nonvolatile memory device according to another embodiment of this disclosure.

Referring to FIG. 4, a nonvolatile memory device according to another embodiment of this disclosure includes one or more memory chips 210, a controller 220, a transfer unit 230, and a voltage detector 240.

Each of the memory chips 210 includes a CAM cell unit 211, a common memory unit 212, a peripheral circuit unit 213, a register unit 214, and a control unit 215. The CAM cell unit 211 stores option information for operating the memory chip 210. The peripheral circuit unit 213 includes a circuit for loading data stored in the CAM cell unit 211 and storing the loaded data into circuits such as a memory cell array and a page buffer which are typically included in the memory chip 210.

The register unit 214 temporarily stores option information stored in the CAM cell unit 211 during the operation of the memory chip 210. The control unit 215 loads information stored in the CAM cell unit 211 in response to an internal command generated by the controller 220 and received via a transfer unit 230, and stores the loaded information in the register unit 214.

The controller 220 generates the internal command for operating the one or more memory chips 110 in response to an external command.

The transfer unit 230 transfers the internal command generated by the controller 220 to the memory chips 210 in response to a detection signal V_det generated by the voltage detector 240.

The voltage detector 240 detects an external power supply voltage Vext. When the external power supply voltage is higher than a certain voltage, the voltage detector 240 outputs the detection signal V_det.

The operation of the nonvolatile memory device according to another embodiment of this disclosure shown in FIG. 4 is described below.

First, the external power supply voltage Vext which gradually rises is supplied to the nonvolatile memory device and powers on the nonvolatile memory device. When the external power supply voltage Vext is supplied, the controller 220 is reset from a standby state. In response to the external command, the controller 220 generates the internal command for operating the memory chips 210.

The voltage detector 240 determines whether the external power supply voltage Vext is higher than a certain voltage and generates the detection signal V_det based on a result of the determination. For example, if the external power supply voltage Vext is equal to or less than the set voltage, the voltage detector 240 does not output the detection signal V_det. If the external power supply voltage Vext is determined to be higher than the set voltage, the voltage detector 240 outputs the detection signal V_det.

If the detection signal outputted by the voltage detector 240 is deactivated, the transfer unit 230 is disabled from transferring the internal command generated by the controller 220 to the memory chips 210. If the external power supply voltage Vext is higher than the set voltage, the voltage detector 240 outputs the detection signal V_det. The transfer unit 230 is enabled to transfer the internal command to the memory chips 210 in response to the detection signal.

The control unit 215 of the memory chips 210 inputs a read command for reading data, where the read command is stored in a CAM cell of the CAM cell unit 211, to the peripheral circuit unit 213 in response to the internal command received via the transfer unit 230.

The peripheral circuit unit 213 reads the data stored in the CAM cell of the CAM cell unit 211 and stores the read data in the register unit 214 via the control unit 215. Next, the nonvolatile memory device performs operations (e.g., program, erase, and read operations) using the data stored in the register unit 214.

As described above, according to an exemplary embodiment, the internal command is sent to the control unit 215 of the memory chip 210 when the external power supply voltage is higher than a set voltage. Data stored in a CAM cell of the CAM cell unit 211 are read and stored in the register unit 214. Accordingly, data stored in a CAM cell can be read more stably, and so reliability of the operations of the nonvolatile memory device can be improved.

As described above, according to exemplary embodiments of this disclosure, an external power supply voltage higher than a certain voltage is detected, and the detection signal is generated in response thereto. The memory chip including the CAM cell unit reads data stored in the CAM cell unit in response to the detection signal. Accordingly, data stored in a CAM cell can be read more stably.

What is claimed is:

1. A nonvolatile memory device, comprising:
a voltage detector for generating a detection signal when an external power supply voltage is higher than a set voltage; and
memory chips, each comprising a memory cell unit and a content-addressable memory (CAM) cell unit and performing internal operations in response to the detection signal.

2. The nonvolatile memory device of claim 1, wherein each of the memory chips comprises:
the CAM cell unit configured to store CAM cell data;
a peripheral circuit unit coupled to the CAM cell unit and configured to read the CAM cell data in response to a read command;
a control unit configured to generate the read command in response to the detection signal; and
a register unit configured to temporarily store the read CAM cell data.

3. A nonvolatile memory device, comprising:
a controller configured to generate an internal command in response to an external command; and
memory chips operated in response to the internal command,
wherein the controller outputs a command for controlling operations of the memory chips when an external power supply voltage is higher than a set voltage.

4. The nonvolatile memory device of claim 3, wherein the command for controlling the operations of the memory chips is a command for reading CAM cell data from the memory chips.

5. The nonvolatile memory device of claim 3, wherein the controller comprises a voltage detector for detecting the external power supply voltage when the external power supply voltage is higher than the set voltage and generating a detection signal.

6. The nonvolatile memory device of claim 5, wherein each of the memory chips comprises:
a CAM cell unit configured to store CAM cell data;
a peripheral circuit unit coupled to the CAM cell unit and configured to read the CAM cell data in response to a read command;
a control unit configured to generate the read command in response to the detection signal; and
a register unit configured to temporarily store the read CAM cell data.

7. A nonvolatile memory device, comprising:
memory chips, each comprising a memory cell unit and a CAM cell unit and performing internal operations in response to an internal command;
a controller for generating the internal command in response to an external command;
a voltage detector for comparing an external power supply voltage and a set voltage and outputting a detection signal based on a result of the comparison; and
a transfer unit for transferring the internal command to the memory chips in response to the detection signal.

8. The nonvolatile memory device of claim 7, wherein the internal command is a command for reading CAM cell data stored in the CAM cell unit.

9. The nonvolatile memory device of claim 7, wherein the voltage detector enables the detection signal when the external power supply voltage is higher than the set voltage.

10. The nonvolatile memory device of claim 7, wherein each of the memory chips comprises:
the CAM cell unit configured to store CAM cell data;
a peripheral circuit unit coupled to the CAM cell unit and configured to read the CAM cell data in response to a read command;
a control unit configured to generate the read command in response to the internal command; and
a register unit configured to temporarily store the read CAM cell data.

11. A method of operating a nonvolatile memory device, the method comprising:
gradually increasing an external power supply voltage;
detecting the external power supply voltage, and generating a read command when the external power supply voltage is higher than a set voltage;
reading CAM cell data in response to a read command and storing the read CAM cell data; and
performing program, read, and erase operations using the stored CAM cell data.

12. The method of claim 11, further comprising resetting a controller for generating, before generating the read command, an internal command in response to an external command.

13. A method of operating a nonvolatile memory device, the method comprising:
gradually increasing an external power supply voltage;
inputting an external command to a controller to thereby generate an internal command;
when the external power supply voltage is higher than a set voltage, transferring the internal command to memory chips;
reading CAM cell data stored in the memory chips in response to the internal command; and
performing program, read, and erase operations using the CAM cell data.
